(19) United States
(12) Patent Application Publication
(10) Pub. No.: US 2007/0033513 A1
(43) Pub. Date: Feb. 8, 2007

(54) Radio communication system, transmitter and decoding apparatus employed in radio communication system

(76) Inventors: Kohsuke Harada, Yokohama-shi (JP); Kaoru Inoue, Machida-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/390,354

(22) Filed: Mar. 28, 2006

(30) Foreign Application Priority Data
Jul. 4, 2005 (JP) 2005-195193

(51) Int. Cl. G06F 11/00; H03M 13/00

(52) U.S. Cl. 714/801

(57) ABSTRACT

Radio-communication-system includes transmitting-station and receiving-station. The transmitting-station includes first-encoding-unit configured to generate plural parity-information by using the different-data, second-encoding-unit configured to encode each of the plural parity-information and each of the different-data to produce plural encoded-data, modulation-unit configured to modulate carriers by the plural encoded-data to generate plural modulated-signals, and multiplex-unit configured to multiplex the plural modulated-signals for outputting a multiplexed-signal. The receiving-station includes demultiplex-unit configured to demultiplex the multiplexed-signal transmitted from the transmitting-station into the plural modulated-signals, demodulation-unit configured to demodulate each of the modulated-signals demultiplexed by the demultiplex-unit to produce plural demodulated-signals, first-decoding-unit configured to decode each of the demodulated-signals according to a decoding-scheme corresponding to an encoding-scheme of the second-encoding-unit to produce plural decoded-signals, and second-decoding-unit configured to decode each of the decoded-signals according to a decoding-scheme corresponding to an encoding-scheme of the first-encoding-unit to obtain the different-data.

### CROSS-REFERENCE TO RELATED APPLICATIONS

This application is based upon and claims the benefit of priority from prior Japanese Patent Application No. 2005-195193, filed Jul. 4, 2005, the entire contents of which are incorporated herein by reference.

### BACKGROUND OF THE INVENTION

1. Field of the Invention

This invention relates to an error-correcting-coding method of a radio communication system such as a code division multiplexing (CDM) broadcast system and, more particularly, to a method of multiplexing an error-correcting-coding bit and decoding thereof.

2. Description of the Related Art

If a code division multiplexing (CDM) broadcast system standardized by ITU-T (International Telecommunication Union-Radio Communication Sector) Recommendation BO. 1130-4, Digital System E. is employed in radio propagation circumstances such as urban areas where a number of multipaths exist, multiplexed signals interfere with each other due to a delay wave caused by the multipaths, and orthogonality of the multiplexed data collapse, and receiving characteristics are thereby remarkably degraded.

In the CDM communication system, the signal delayed by the multipaths is effectively used by employing the RAKE receiving scheme and the diversity gain is acquired, to restrict the degradation in the receiving characteristics caused by the multipaths (for example, Jpn. Pat. Appln. KOKAI No. 2004-80360). In addition, to remove the influence of the interference caused by the multipaths, the received CDM signal is subjected to canceling which removes the interference signal from the received signal, by using a demodulation result of the multiplexed data.

However, since the conventional RAKE receiving scheme and canceling need to be applied to the received signal itself, the processing needs to be executed at a high speed, with high accuracy, on the receiving side. This makes reduction of the power consumption on the receiving side difficult.

Particularly, if the CDM scheme is applied to the radio communication system, spread spectrum processing to multiplex the data by code division needs to be executed at a very high speed as compared with the transmission ratio of the transmitted data. In the receiver, too, the processing needs to be executed at a high speed as compared with the transmission data ratio. This processing is therefore said to be very inefficient. In other words, since a chip which operates at a higher speed than the data rate needs to be used for the CDM, application of the CDM to the receiving on a portable terminal is not efficient in view of the processing speed.

### BRIEF SUMMARY OF THE INVENTION

An aspect of the present invention provides a radio communication system with a transmitting station which multiplexes different data and transmits multiplexed data to a receiving station. The transmitting station comprises a first encoding unit configured to generate plural parity information by using the different data, a second encoding unit configured to encode each of the plural parity information and each of the different data to produce plural encoded data, a modulation unit configured to modulate carriers by the plural encoded data to generate plural modulated signals, and a multiplex unit configured to multiplex the plural modulated signals for outputting a multiplexed signal. The receiving station comprises a receiving station comprising a demultiplex unit configured to demultiplex the multiplexed signal transmitted from the transmitting station into the plural modulated signals, a demodulation unit configured to demodulate each of the modulated signals demultiplexed by the demultiplex unit to produce plural demodulated signals, a first decoding unit configured to decode each of the demodulated signals according to a decoding scheme corresponding to an encoding scheme of the second encoding unit to produce plural decoded signals, and a second decoding unit configured to decode each of the decoded signals according to a decoding scheme corresponding to an encoding scheme of the first encoding unit to obtain the different data.

### BRIEF DESCRIPTION OF THE SEVERAL VIEWS OF THE DRAWING

FIG. 1 is a block diagram showing a configuration of a transmitting station in a radio communication system;

FIG. 2 is a block diagram showing a configuration of a receiving station corresponding to the transmitting station shown in FIG. 1;

FIG. 3 is a block diagram showing a configuration of a transmitting station in a radio communication system;

FIG. 4 is an illustration for explanation of a signal transmitted from the transmitting station shown in FIG. 3;

FIG. 5 is a block diagram showing a configuration of a receiving station corresponding to the transmitting station shown in FIG. 3;

FIG. 6 is a block diagram showing a configuration of a transmitting station in a radio communication system;

FIG. 7 is an illustration for explanation of a signal transmitted from the transmitting station shown in FIG. 6;

FIG. 8 is a block diagram showing a configuration of a receiving station corresponding to the transmitting station shown in FIG. 6;

FIG. 9 is a block diagram showing a configuration of a transmitting station in a radio communication system according to the present invention;

FIG. 10 is an illustration for explanation of encoding in an encoder 90 of the transmitting station shown in FIG. 9;

FIG. 11 is a block diagram showing a configuration of a receiving station corresponding to the transmitting station shown in FIG. 9;

FIG. 12 is a block diagram showing a configuration of a receiving station corresponding to the transmitting station shown in FIG. 9;

FIG. 13 is an illustration for explanation of encoding in an encoder 90 of the transmitting station shown in FIG. 9;

FIG. 14 is an illustration for explanation of encoding in an encoder 90 of the transmitting station shown in FIG. 9;

FIG. 15 is an illustration for explanation of generation of parity bit sequences;

FIG. 16 is a block diagram showing a configuration of a transmitting station which executes the encoding shown in FIG. 15;

FIG. 17 is a block diagram showing a configuration of a receiving station corresponding to the transmitting station shown in FIG. 16;

FIG. 18 is a block diagram showing a modified configuration of the transmitting station shown in FIG. 9;

FIG. 19 is a block diagram showing a configuration of a receiving station corresponding to the transmitting station shown in FIG. 18;

FIG. 20 is a block diagram showing a modified configuration of the transmitting station shown in FIG. 9;

FIG. 21 is a block diagram showing a configuration of a receiving station corresponding to the transmitting station shown in FIG. 20;

FIG. 22 is a block diagram showing a configuration of a transmitting station in a code division multiplexing broadcast system based on ITU-R Recommendation;

FIG. 23 is a block diagram showing a configuration of a receiving station corresponding to the transmitting station shown in FIG. 22;

FIG. 24 is a block diagram showing a configuration of the transmitting station in the code division multiplexing broadcast system based on ITU-R Recommendation to which the transmitting station shown in FIG. 9 is applied;

FIG. 25 is a block diagram showing a configuration of a receiving station corresponding to the transmitting station shown in FIG. 24;

FIG. 26 is a graph showing a received bit error rate characteristic in a radio broadcast system comprising the transmitting station shown in FIG. 24 and the receiving station shown in FIG. 25; and

FIG. 27 is an illustration showing a configuration of a radio communication system to which the transmitting station shown in FIG. 9 is applied.

### DETAILED DESCRIPTION OF THE INVENTION

Embodiments of the present invention will be explained below with reference to the accompanying drawings.

FIG. 1 shows a configuration of a transmitting station in a radio communication system. In the transmitting station, information bit sequences of different information items 11a, 11b, 11c are encoded by encoders 12a, 12b, 12c corresponding thereto. With the obtained encoded bit sequences, carriers are modulated by modulators 13a, 13b, 13c corresponding thereto. These modulation results are multiplexed by a multiplexer 14 and then transmitted.

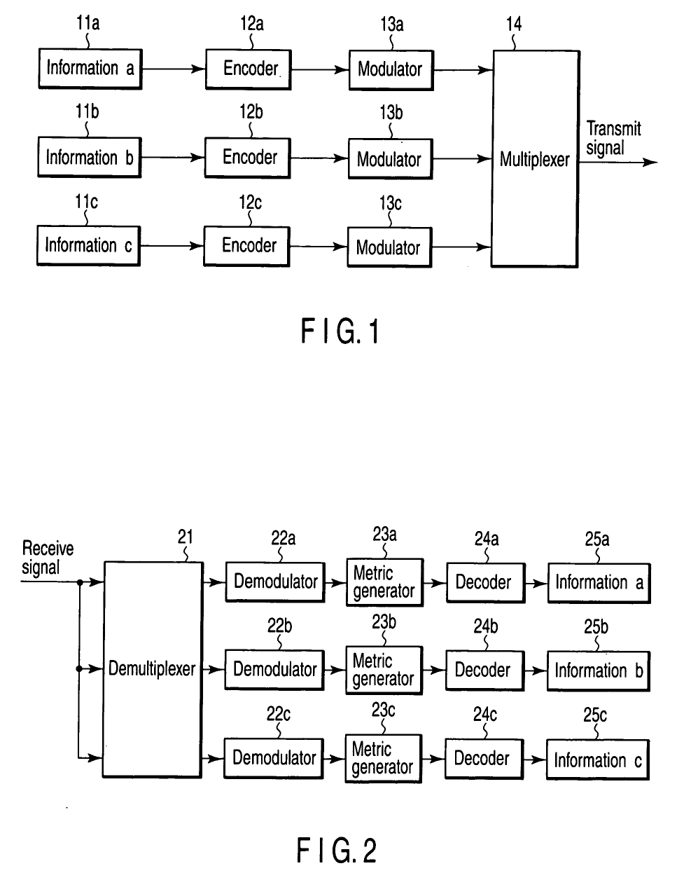

In the communication system employing such a transmitting station, a receiving station has a configuration shown in FIG. 2. In the receiving station, the receive signal multiplexed by the multiplexer 14 is separated for each of the encoded bit sequences by a demultiplexer 21. The receive signals thus separated are detected by demodulators 22a, 22b, 22c, respectively.

Metric generators 23a, 23b, 23c generate metric values on the basis of the detection results which correspond respectively to the metric generators. The metric values thus generated are decoded by decoders 24a, 24b, 24c, respectively, and desired information bit sequences 25a, 25b, 25c are thereby obtained.

If the above-described encoding is executed in the transmitting station, decoding corresponding to the encoders 12a, 12b, 12c of the transmitting station can be executed independently of each other by the decoders 24a, 24b, 24c, in the receiving station. However, the receiving characteristics of the decoding depend on the only encoding of the encoded bit sequences.

In general, if multiplexing is executed in the transmitting station as shown in FIG. 1, transmit signals corresponding to the respective encoded bit sequences are mutually orthogonalized and then multiplexed. For this reason, the multiplexed transmit signals can be separated without interference at the receiving station unless their orthogonality is broken in the communication path.

If their orthogonality is broken in the communication path, the transmit signals corresponding to the multiplexed encoded bit sequences cannot be separated without interference at the receiving station. The transmit signals interfere with each other and the receiving characteristics are thereby degraded.

As for the method of orthogonalizing the multiplexed transmit signals on the transmitting side, Code Division Multiple Access (CDMA) or Orthogonal Frequency Division Multiplexing (OFDM) is employed.

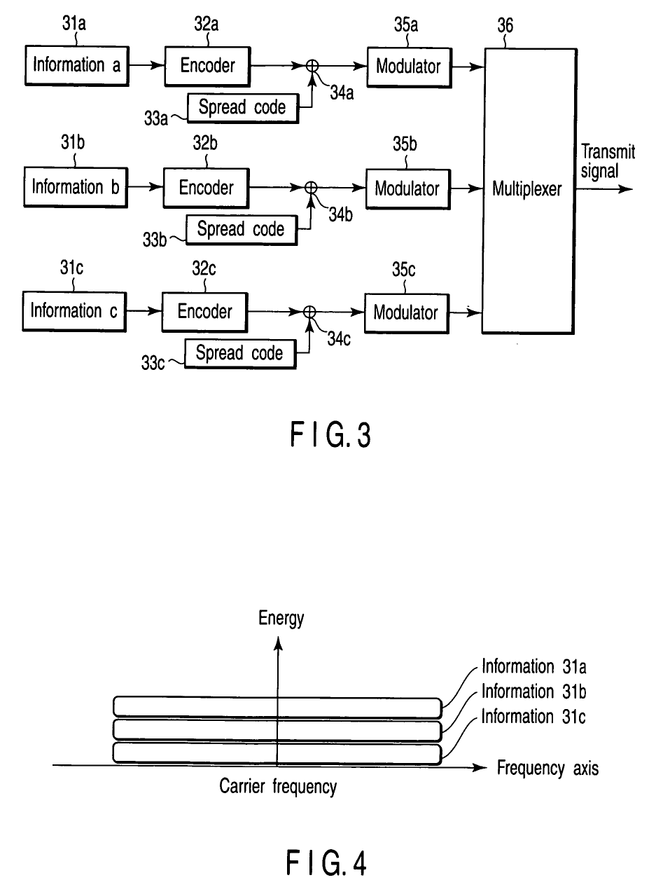

A communication system employing the CDM scheme will be explained here. FIG. 3 shows a configuration of the transmitting station in the communication system. In the transmitting station, information bit sequences of different information items 31a, 31b, 31c are encoded by encoders 32a, 32b, 32c, respectively.

The encoded bit sequences thus obtained are multiplexed with spread code sequences 33a, 33b, 33c by multiplexers 34, 34b, 34c, respectively, and then spread. The spread code sequences 33a, 33b, 33c orthogonalize each other.

The multiplexing results thus obtained are used for modulation of carriers in modulators 35a, 35b, 35c, respectively. The modulation results are multiplexed by a multiplexer 36 and then transmitted. The transmit signal thus spread is transmitted in a state in which energies are multiplexed as shown in FIG. 4.

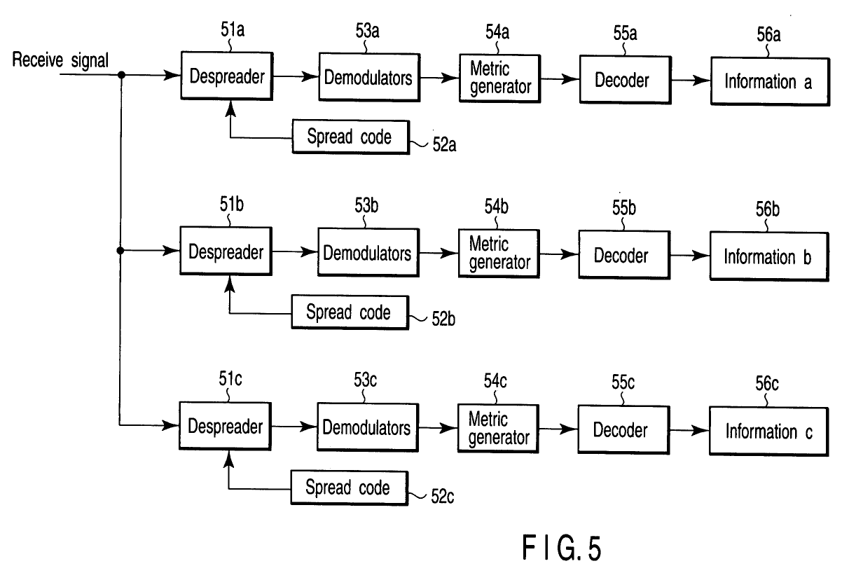

In the communication system using this transmitting station, the receiving station has a configuration shown in FIG. 5. In this receiving station, the receive signal is multiplexed with spread code sequences 52a, 52b, 52c by despreaders 51a, 51b, 51c, respectively, and separated in accordance with the information bit sequences of information items 31a, 31b, 31c.

The receive signals thus separated are detected by demodulators 53a, 53b, 53c, respectively. Metric generators 54a, 54b, 54c generate metric values on the basis of the respective detection results. The metric values thus generated are decoded by decoders 55a, 55b, 55c, respectively and desired information bit sequences 56a, 56b, 56c are thereby obtained.

However, if orthogonality of the multiplexed transmit signals cannot be maintained due to the multipath or for the reason that synthesis is not made between the multiplexed transmit signals, the multiplexed signals interfere with each other and cannot be separated ideally, and the receiving characteristics are therefore degraded.

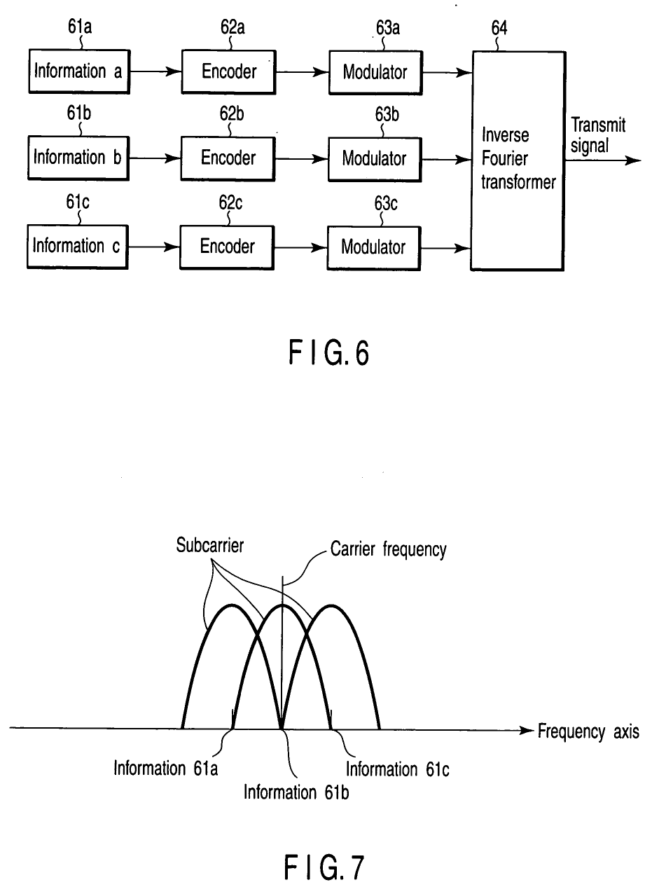

Next, a communication system employing the OFDM scheme will be explained here. FIG. 6 shows a configuration of the transmitting station in the communication system. In the transmitting station, information bit sequences of different information items 61a, 61b, 61c are encoded by encoders 62a, 62b, 62c, respectively.

The encoded bit sequences thus obtained are used for modulation of carriers in modulators 63a, 63b, 63c, respectively. The modulation results are subjected to inverse Fourier transform by an inverse Fourier transformer 64 such that signals in the frequency axis are transformed into signals of a time axis waveform, which are then multiplexed. Thus, orthogonality of the data multiplexed in the OFDM is maintained in the frequency axis as shown in FIG. 7.

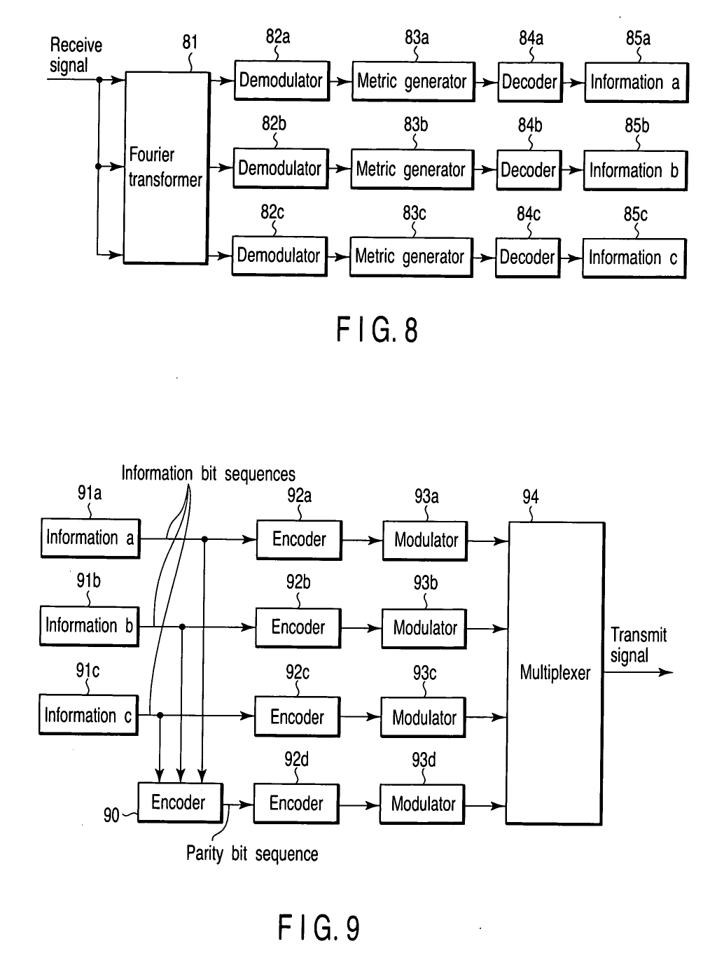

In the communication system employing such a transmitting station, a receiving station has a configuration shown in FIG. 8. In the receiving station, the receive signal is subjected to Fourier transform and separated into transmit signals in the frequency axis shown in FIG. 7 by a Fourier transformer 81, and desired receive signals are thereby obtained.

The receive signals thus separated are detected by demodulators 82a, 82b, 82c, respectively. Metric generators 82a, 82b, 82c generate metric values on the basis of the detection results which correspond respectively to the metric generators. The metric values thus generated are decoded by decoders 84a, 84b, 84c, respectively, and desired information bit sequences 85a, 85b, 85c are thereby obtained.

In this communication system, too, if the orthogonality cannot be maintained on the receiving side due to influence from the multipath in the communication path, etc., the multiplexed transmit signals interfere with each other and receiving characteristics are thereby degraded.

In any one of the above-explained communication systems, multiplexing and encoding are independently executed for the multiplexed data. Since correlation information in the communication path caused by multiplexing cannot be used, optimum receiving cannot be executed.

In addition, although the data to be multiplexed on the transmitting side and the receiving side need to be encoded and decoded at many costs, the correlation information of the multiplexed data, in the communication path, is not used. Therefore, only improvement effect of the receiving characteristics based on separate encoding can be obtained on the receiving side. From the viewpoint of efficiency in the transmission and receiving, in the communication system in which the data is multiplexed, the receiving characteristics of the data to be multiplexed should preferably be obtained in accordance with the data amount.

The present invention provides a radio communication system capable of executing optimum receiving by effectively using the correlation information of the multiplexed data in the communication path. Improvement of the receiving characteristics can be expected without requiring a higher processing than the transmission data ratio on the receiving side, if error correction capable of reducing the influence from the interference caused by the multipath is applied to the data error which occurs due to the influence from the channel. In particular, since decoding of error correction can be executed at a processing speed proportional to the transmission data ratio, the receiving characteristics can be efficiently improved without a high-speed processing.

Then, the present invention proposes a manner of optimally receiving the multiplexed data which interfere with each other by the multipath, etc., by adding the encoding based on the encoded sequences to be multiplexed to the communication system. In the proposed scheme, since the receiving characteristics of all the multiplexed data can be obtained in accordance with their processing amount, the receiving characteristics can be efficiently improved.

FIG. 9 shows a configuration of a transmitting station in a radio communication system according to an embodiment of the present invention. In the transmitting station, information bit sequences of information items 91a, 91b, 91c are encoded by encoders 92a, 92b, 92c, respectively.

Simultaneously with this, an encoder 90 executes encoding by using the information bit sequences of the information items 91a, 91b, 91c. In other words, the encoders 92a, 92b, 92c encode the information bit sequences of the information items 91a, 91b, 91c, respectively, while the encoder 90 executes encoding by using the information bit sequences.

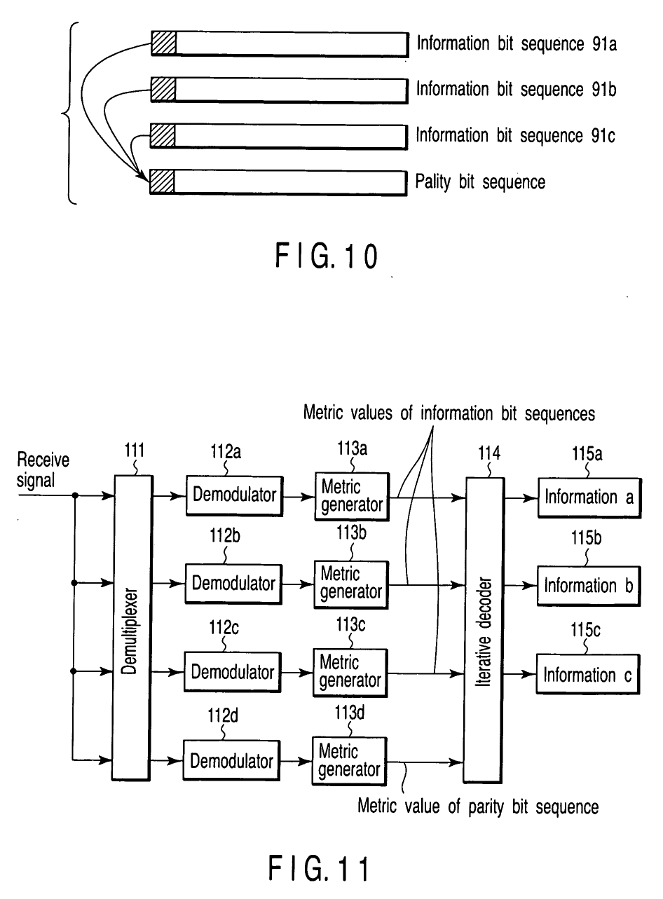

Encoding executed by the encoder 90 generates parity bit sequences by using the information bit sequences of the information items 91a, 91b, 91c as shown in, for example, FIG. 10. An encoder 92d encodes the parity bit sequence generated by the encoder 90 in the same manner as the encoders 92a, 92b, 92c and thereby obtains an encoded bit sequence.

The modulators 93a, 93b, 93c, 93d modulate carriers by using the encoded bit sequences obtained by the encoders 92a, 92b, 92c, 92d, respectively. The modulation results are multiplexed by a multiplexer 94 and then transmitted.

In the communication system employing such a transmitting station, a receiving station has a configuration shown in FIG. 11. In the receiving station, the receive signal multiplexed by the multiplexer 94 is separated for each of the encoded bit sequences by a demultiplexer 111. The receive signals thus separated are detected by demodulators 112a, 112b, 112c, 112d, respectively.

Metric generators 113a, 113b, 113c, 113d generate metric values on the basis of the detection results which correspond respectively to the metric generators. The metric generators 113a, 113b, 113c correspond to the encoders 92a, 92b, 92c, respectively. The metric generator 113d corresponds to the encoder 92d and encoder 90.

For this reason, the metric values corresponding to the information bit sequences of the information items 91a, 91b, 91c can be obtained by the metric generators 113a, 113b, 113c, respectively. In addition, the metric value corresponding to the parity bit sequence which is output from the encoder 90 can be obtained by the metric generator 113d.

In an iterative decoder 114, the metric values obtained by the metric generators 113a, 113b, 113c, 113d are subjected to decoding corresponding to the encoding of the encoders 92a, 92b, 92c, 92d. In the iterative decoder 114, the result of decoding corresponding to the encoding of the encoders 92a, 92b, 92c, 92d is also subjected to decoding corresponding to the encoding of the encoder 90. Iterative decoding is executed by using the decoding results and desired information bit sequences 115a, 115b, 115c are thereby obtained.

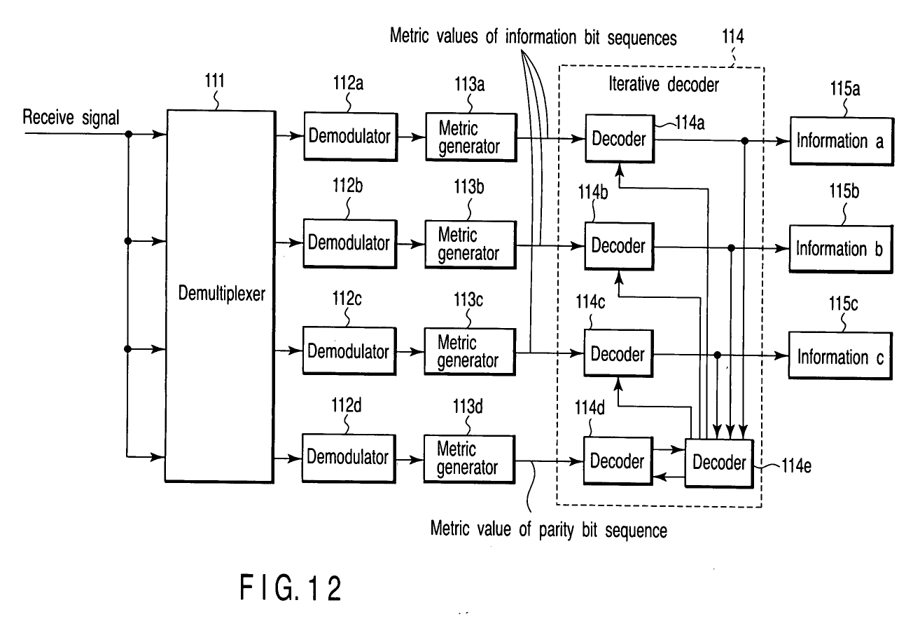

FIG. 12 shows details of the configuration of the iterative decoder 114. In the iterative decoder 114, the metric values obtained by the metric generators 113a, 113b, 113c, 113d are subjected to decoding corresponding to the encoding of the encoders 92a, 92b, 92c, 92d, by decoders 114a, 114b, 114c, 114d, respectively.

In a decoder 114e, the decoding results of the decoders 114a, 114b, 114c, 114d are subjected to decoding corresponding to the encoding of the encoder 90 and bit sequences corresponding to the information items 91a, 91b, 91c are thereby obtained. On the basis of the decoding corresponding to the encoder 90, the decoder 114e further decodes the decoding results of the decoders 114a, 114b, 114c, 114d and outputs the decoding results to the decoders 114a, 114b, 114c, 114d, respectively. The decoders 114a, 114b, 114c, 114d executes the decoding again on the basis of the decoding results of the decoder 114e.

After that, decoding of the decoders 114a, 114b, 114c, 114d and the decoding of the decoder 114e are iterated. When error is lowered below a predetermined level soon, the desired information items 115a, 115b, 115c are taken out.

A method of acquiring the decoding results of the decoders 114a,114b, 114c, 114d and the decoding result of the decoder 114e will be described in detail.

For example, if one bit is taken from each of different data items to be multiplexed to generate parity data satisfying even parity, the parity bit is defined in the following formula:
bit1⊕bit2⊕bit3⊕parity=0
where bit 1, bit 2, bit 3 represent information bits to be multiplexed, respectively. The parity indicates the parity bit generated by the encoder 90 in FIG. 9. If encoding is executed in this manner, bit 1, bit 2, bit 3 are also encoded by the encoders 92a, 92b, 92c independently of the parity generated by the encoder 90. Thus, they can be decoded by the decoders 114a, 114b, 114c without using the parity bit on the receiving side.

The iterative decoding of the decoders 114a, 114b, 114c, 114d and the decoder 114e will be explained here. If the parity bit sequence generated by the encoder 90 is multiplexed with the above-explained data to be multiplexed, in a receiving station shown in FIG. 12, the parity bit is defined on the basis of the multiplexed data.

In the receiving station, first, the decoding corresponding to the encoders 92a, 92b, 92c, 92d is executed by the decoders 114a, 114b, 114c, 114d and a Soft-decision posteriori probability value is acquired by Maximum A-posteriori Probability (MAP) decoding, in relation to each of the multiplexed information bit sequences and the parity bit sequence generated by the encoder 90.

As algorithms for the MAP decoding, Bahl Cocke Jelinek Raviv (BCJR) algorithm, min-sum algorithm, Soft Output Viterbi Algorithm (SOVA) and the like are employed.

The posteriori probability value obtained by the MAP algorithm is acquired by the following formula, in relation to each of the multiplexed information bit sequences and the parity bit sequence, in the decoders 114a, 114b, 114c, 114d.
Pr[bit=a|r]=p(r|bit=a)Pr[bit=a]
where r represents a metric value for each of the receive signals obtained by separating the multiplexed receive signal. p(r|bit=a) represents a probability density function of the receive signal where the information bit which is the origin of each of the encoded bits generated by the encoders 92a, 92b, 92c, 92d is a. Pr[bit=a] represents the prior probability at which the information bit input to each of the encoders 92a, 92b, 92c, 92d is a. Pr[bit=a|r] represents the posteriori probability at which the information bit bit=a is transmitted under the condition that r is received.

MAP decoding is executed again by using the decoding results for the encoders 92a, 92b, 92c, 92d, i.e. the posteriori probability values Pr[bit=a|r] as the metric values in the decoding of the decoder 114e. The posteriori probability values for the parity bit sequence obtained by the encoding of the encoder 90 are acquired in the following formula:
Pr[bit′=a|r]=Pr[bit=a|r]Pr[bit′=a]={p(r|bit=a)Pr[bit=a]}*Pr[bit′=a]
Pr[bit′=a|r] represents the posteriori probability at which the information bits input to the encoder 90 are bit′=a under the condition that the receive signal r is received. Pr[bit′=a|r] represents the prior probability at which the information bits input to the encoder 90 are a.

The data of the information bit sequences encoded by the encoders 92a, 92b, 92c are further encoded by the encoder 90 provided independently of the encoders 92a, 92b, 92c. In other words, two kinds of encoding are executed.

In this case, gains Pr[bit=a] of the encoders 92a, 92b, 92c and gain Pr[bit′=a] of the encoder 90 can be obtained simultaneously, in relation to desired information bit a and the reliability can be thereby made higher.

Moreover, since prior information Pr[bit=a] of the decoders 114a, 114b, 114c, 114d and prior information Pr[bit′=a] of the decoder 114e can be acquired independently of each other, decoding is iterated in the configuration of FIG. 12 consisting of the decoders 114a, 114b, 114c, 114d the decoder 114e, by using the gain Pr[bit′=a] acquired by the decoder 114e as the prior information used in the decoders 114a, 114b, 114c, 114d and, and using the gain Pr[bit=a] acquired by the decoders 114a, 114b, 114c, 114d as the prior information used in the decoder 114e. The reliability can be thereby made higher.

At the first decoding, the prior probability Pr[bit=a] of the encoded bit sequences
Pr[bit=0]=0.5
Pr[bit=1]=0.5
   the above-described decoding is iterated.

In the communication system having the above-described configuration, the parity bit sequence is generated by using the information bit sequences of the respective information items 91a, 91b, 91c, the parity bit sequence and the modulation results based on the information bit sequences are multiplexed and transmitted, in the transmitting station. The parity bit sequence is decoded and the information bit sequences are decoded by using the decoded parity bit sequence, in the receiving station.

Therefore, even if the orthogonality of a plurality of multiplexed information bit sequences cannot be maintained in the communication path, degradation in the receiving characteristics can be restricted. In relation to the data multiplexed in the transmitting station, the gains can be obtained by decoding the information bit sequences in the decoders 114a, 114b, 114c, 114d and decoding the parity data in the decoder 114e, in the receiving station. The receiving characteristics can be thereby improved as compared with the receiving of FIG. 2.

The processing necessary to obtain this advantage is executed in the data decoding step. A high-speed receiving which removes the influence from the interference in a state in which the data are multiplexed as seen in the prior art does not need to be executed. The processing can be implemented at the speed proportional to the transmission data ratio and the efficiency can be thereby improved.

In the receiving station shown in FIG. 12, decoding of the decoders 114a, 114b, 114c, 114d and decoding of the decoder 114e are iterated. Since the correlation of the multiplexed data in the communication path and the influence from the interference caused by the multipath or the like can be used for decoding of all of the multiplexed data items, receiving quality is improved.

The signal transmitted from the transmitting station shown in FIG. 9 is obtained by multiplexing the information bit sequences and the parity bit sequence. These bit sequences are quite independent of each other. For this reason, even the receiving station as shown in FIG. 2 can receive the signal, similarly to the case of receiving the signal transmitted from the transmitting station shown in FIG. 1, without receiving the parity bit sequence alone. The receiving quality is also equal to that in the case of receiving the signal transmitted from the transmitting station shown in FIG. 1.

For this reason, an environment in which the receiving station shown in FIG. 2 and the transmitting station shown in FIG. 9 exist together can be applied to the communication system. The communication system having the above-described configuration is also effective for CDM, OFDM or other multiplexing schemes.

Incidentally, generation of the parity bit sequence has been explained above as an additional pattern of the parity bit as shown in FIG. 10. In relation to such a parity bit sequence, multiplexed data associated with a certain parity bit are also the same time as a symbol in which the data are multiplexed and transmitted. For this reason, if the reliability of receiving of the symbol is remarkably deteriorated in the communication path due to the fading or the like, the reliability of the decoding results for all of the data assigned to the symbol becomes deteriorated.

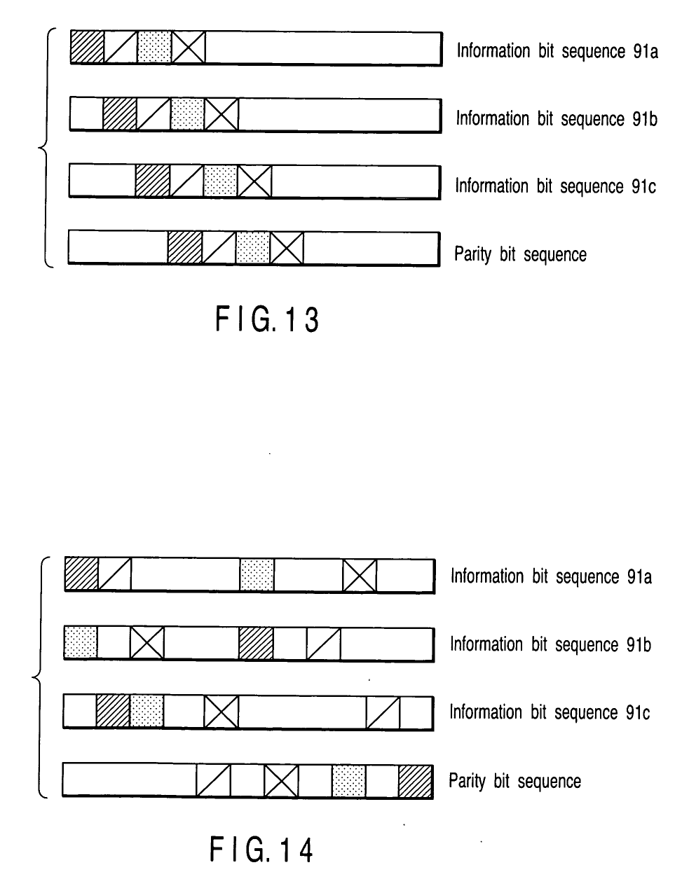

Thus, to generate the parity bit sequence, bits of the used data may be made different in time, in the information bit sequences as shown in FIG. 13. If the parity bit sequence is generated in this manner, the bits of the data included in the symbol which are multiplexed and simultaneously transmitted, are assigned to symbols to be transmitted at different times. For this reason, even if the reliability of one symbol in a certain multiplexed transmit signal becomes deteriorated, the influence from the lower reliability can be dispersed since the signals used for the decoding of the parity bit sequence are assigned to different symbols.

In addition, a generation pattern of the parity bit sequence may not be uniformly defined as shown in FIG. 13, but may be defined in such a manner that bits of random times are selected from the multiplexed data as shown in FIG. 14.

If the parity bit sequence is generated, the bits used for decoding of the parity bit sequence are assigned to multiplexed symbols different in time, as shown in FIG. 14. For this reason, the influence from the lower reliability of the data multiplexed at the same time due to the fading or the like can be further dispersed, and the receiving characteristics can be further improved.

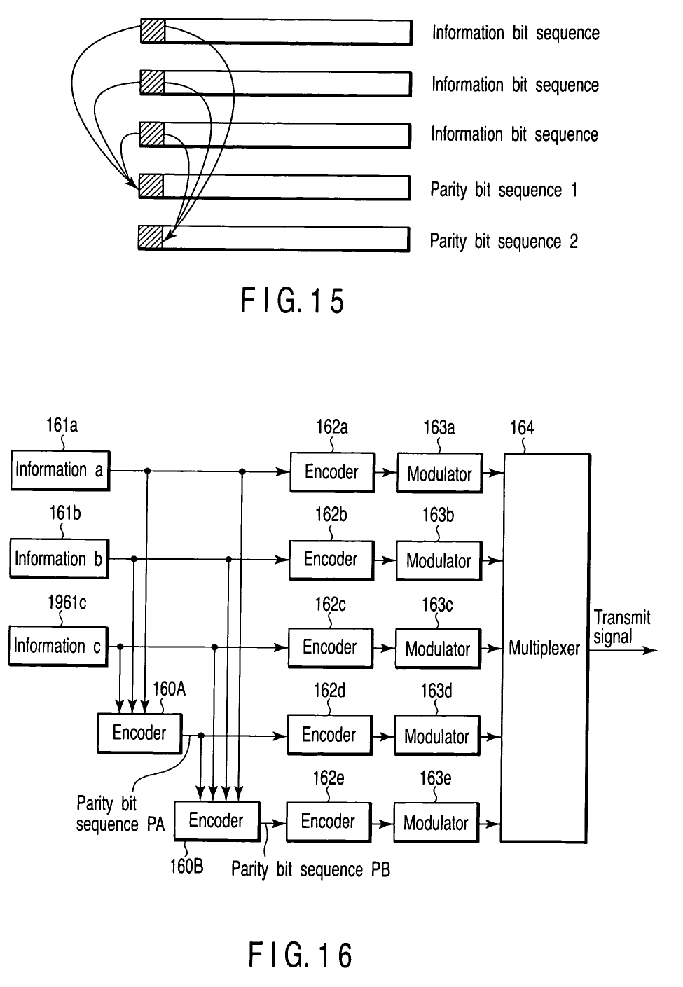

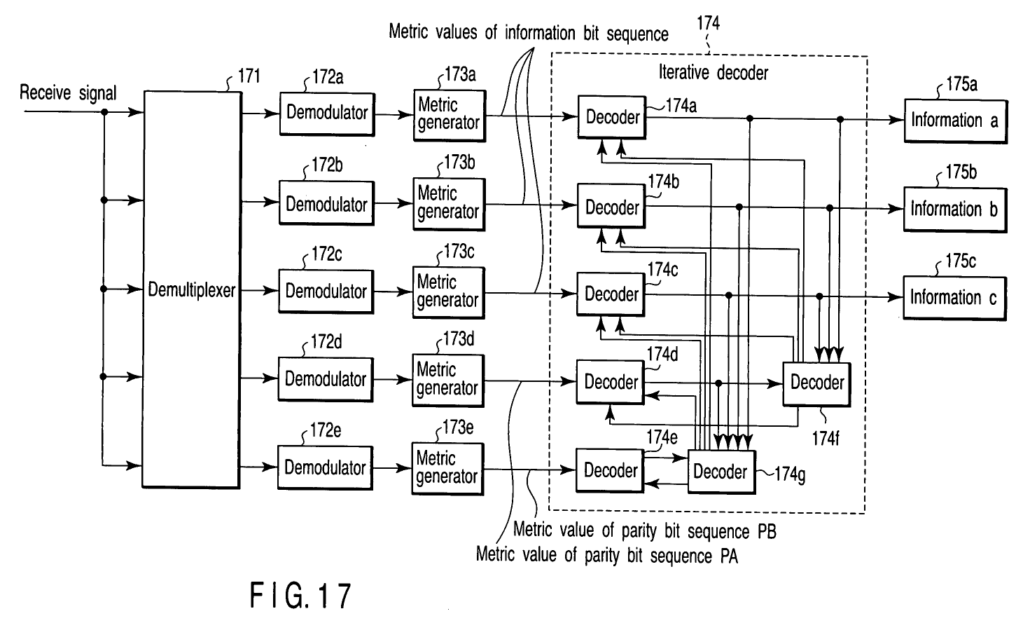

Moreover, parity bit sequences may be generated in different encoding processings as shown in FIG. 15. If parity bit sequences are generated in this manner, encoding is executed in a transmitting station having a configuration shown in FIG. 16 while decoding is executed in a receiving station having a configuration shown in FIG. 17.

In the transmitting station shown in FIG. 16, information bit sequences of different information items 161a, 161b, 161c are encoded by encoders 162a, 162b, 162c, respectively.

An encoder 160A executes encoding by using the information bit sequences of the respective information items 161a, 161b, 161c. An encoder 160B executes encoding by using the encoding result of the encoder 160A and the information bit sequences of the respective information items 161a, 161b, 161c. As shown in FIG. 15, for example, a parity bit sequence is generated by using the information bit sequences of the respective information items 161a, 161b, 161c, in the encoding of the encoder 160A while a parity bit sequence is generated by using the encoding result of the encoder 160A and the information bit sequences of the respective information items 161a, 161b, 161c, in the encoding of the encoder 160B.

In an encoder 162d, the parity bit sequence generated by the encoder 160A is subjected to the same encoding as the encoders 162a, 162b, 162c and an encoded bit sequence is thereby obtained. Similarly, in an encoder 162e, the parity bit sequence generated by the encoder 160B is subjected to the same encoding as the encoders 162a, 162b, 162c and an encoded bit sequence is thereby obtained.

Modulators 163a, 163b, 163c, 163d, 163e modulate carriers by using the encoded bit sequences of the respective encoders 162a, 162b, 162c, 162d, 162e. These modulation results are multiplexed by a multiplexer 164 and then transmitted.

In the receiving station shown in FIG. 17, the receive signal multiplexed by the multiplexer 164 is separated for the respective encoded bit sequences by a demultiplexer 171. The receive signals thus separated are detected by demodulators 172a, 172b, 172c, 172d, 172e, respectively.

On the basis of the detection results of the demodulators 172a, 172b, 172c, 172d, 172e, metric generators 173a, 173b, 173c, 173d, 173e generate metric values, respectively. The metric generators 173a, 173b, 173c correspond to the encoders 162a, 162b, 162c, respectively. The metric generator 173d corresponds to the encoders 162d and 160A. The metric generator 173e corresponds to the encoders 162e and 160B.

For this reason, the metric values corresponding to the information bit sequences of the information bit sequences 161a, 161b, 161c are obtained by the metric generators 173a, 173b, 173c. The metric value corresponding to the parity bit sequence output from the encoder 160A is obtained by the metric generator 173d. The metric value corresponding to the parity bit sequence output from the encoder 160B is obtained by the metric generator 173e.

In an iterative decoder 174, the metric values obtained by the metric generators 173a, 173b, 173c, 173d, 173e are subjected to decoding corresponding to the encoding of the encoders 162a, 162b, 162c, 162d, 162e, by decoders 174a, 174b, 174c, 174d, 174e, respectively.

The decoding results of the decoders 174a, 174b, 174c, 174d are subjected to decoding corresponding to the encoding of the encoder 160A, by a decoder 174f. The decoding results of the decoders 174a, 174b, 174c, 174d, 174e are subjected to decoding corresponding to the encoding of the encoder 160B, by a decoder 174g.

On the basis of the parity bit sequence corresponding to the encoder 160A, the decoder 174f outputs the decoding results of the decoders 174a, 174b, 174c, 174d to the decoders 174a, 174b, 174c, 174d, respectively. The decoders 174a, 174b, 174c, 174d execute decoding again, on the basis of the corrected decoding results.

On the basis of the parity bit sequence corresponding to the encoder 160B, the decoder 174g outputs the decoding results of the decoders 174a, 174b, 174c, 174d, 174e to the decoders 174a, 174b, 174c, 174d, 174e, respectively. The decoders 174a, 174b, 174c, 174d, 174e execute decoding again, on the basis of the corrected decoding results.

After that, decoding of the decoders 174a, 174b, 174c, 174d, 174e and the error correction of the decoders 174g and 174f are iterated. When error is lowered below a predetermined level soon, the desired information items 175a, 175b, 175c are taken out.

In the communication system of the above-described configuration, too, even if the orthogonality of the multiplexed information bit sequences cannot be maintained in the communication path, degradation in the receiving characteristics can be restricted, similarly to the communication system shown in FIG. 9 or FIG. 11.

In relation to the data multiplexed in the transmitting station, the gains can be obtained by decoding the information bit sequences in the decoders 174a, 174b, 174c, 174d, 174e and decoding the parity data in the decoders 174f and 174g, in the receiving station. The receiving characteristics can be thereby improved as compared with the receiving of FIG. 2.

In addition, parity bit generation using different information bit sequences is multiplexed. For example, the reliability in the decoding result of the encoder 160A in FIG. 16 may be deteriorated due to influence from the fading or the like. If the decoding result of the encoder 160B has a small influence from the fading or the like, the reliability can be improved effectively. For this reason, the influence from the lower reliability in the communication path can be further dispersed and the receiving characteristics can be improved.

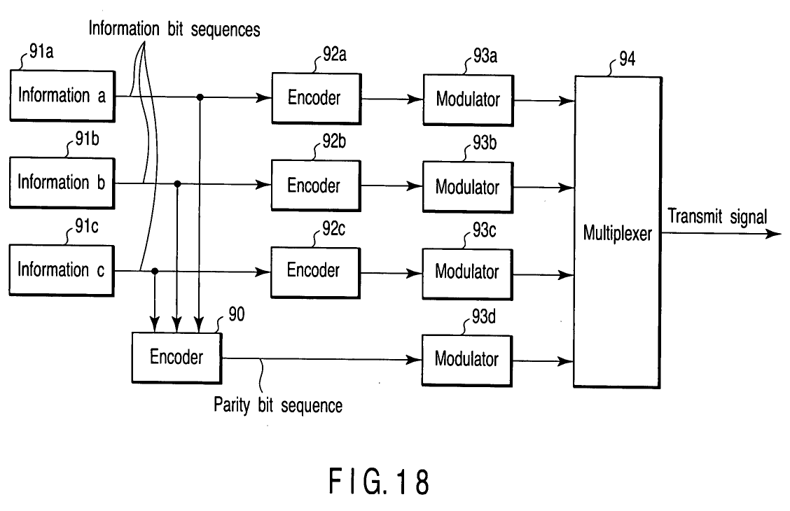

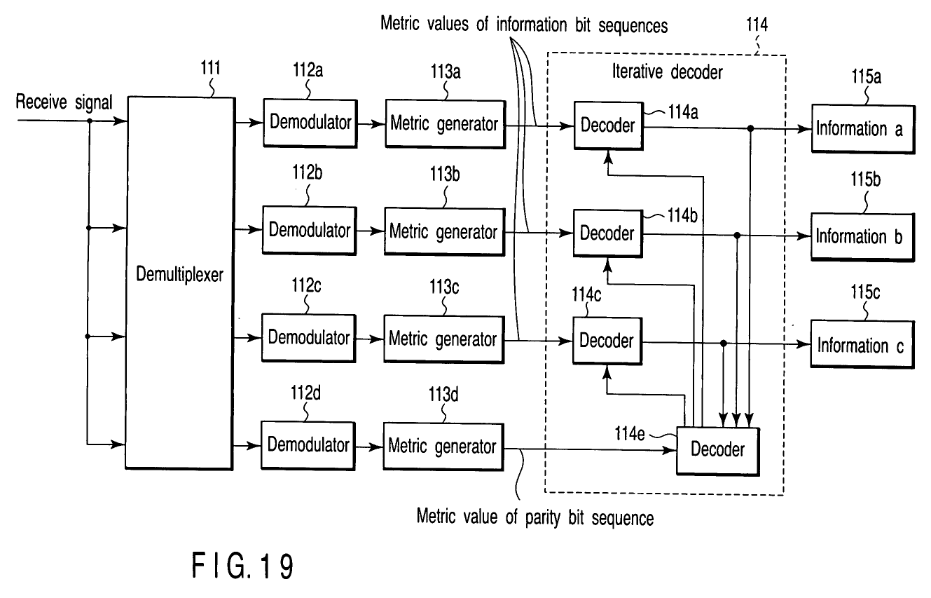

In the transmitting station shown in FIG. 9, the parity bit sequence generated by the encoder 90 is further encoded by the encoder 92d. However, the encoder 92d may be omitted in the receiving station of FIG. 9 as seen in the transmitting station shown in FIG. 18. If such a transmitting station is employed, the receiving station has a configuration shown in FIG. 19. In other words, the decoder 114d corresponding to the encoder 92d is omitted in the receiving station shown in FIG. 12.

According to the communication system having such a configuration, load of the encoding in the transmitting station and load of the decoding in the receiving station can be reduced. The reliability is deteriorated as compared with the communication system shown in FIG. 9 or FIG. 12 but the receiving characteristics can be improved since correlation of the multiplexed data in the communication path are used in the similar manner.

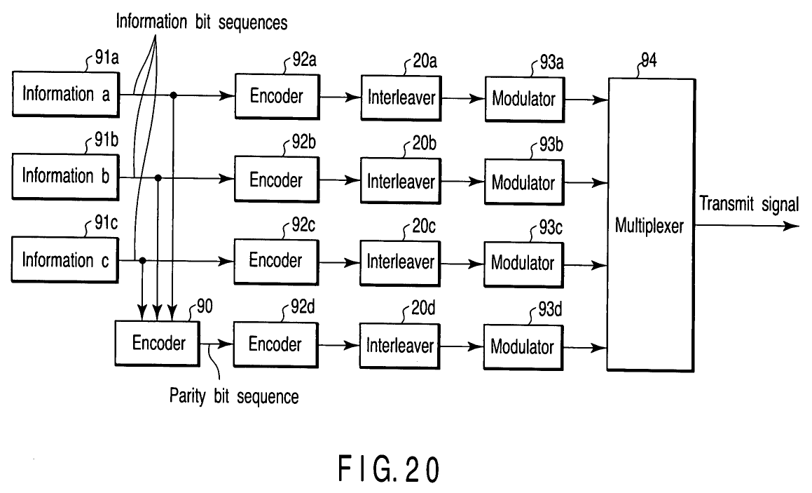

Moreover, to disperse the deterioration in the reliability of the receiving symbol caused by successive fading in the communication path or the like, it is effective to interleave the encoded data. FIG. 20 shows a configuration of a transmitting station which executes the interleaving processing.

In the transmitting station shown in FIG. 20, interleavers 20a, 20b, 20c, 20d are added to the transmitting station shown in FIG. 9. The interleavers 20a, 20b, 20c, 20d interleave the encoding results of the encoders 92a, 92b, 92c, 92d, respectively. The modulators 93a, 93b, 93c, 93d modulate carriers by using the processing results of the interleavers 20a, 20b, 20c, 20d.

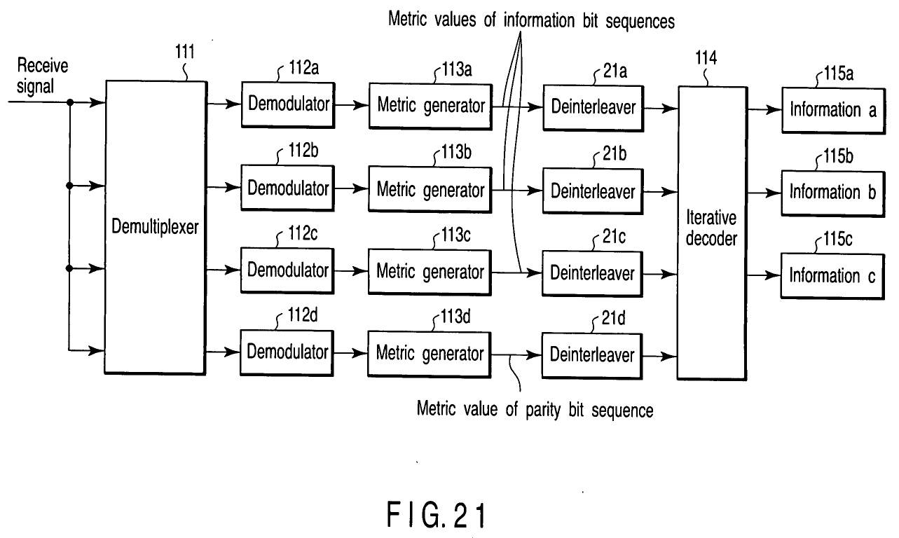

On the other hand, the receiving station has a configuration shown in FIG. 21. In the receiving station shown in FIG. 21, deinterleavers 21a, 21b, 21c, 21d are added to the receiving station shown in FIG. 11.

The deinterleavers 21a, 21b, 21c, 21d deinterleave the metric values acquired by the metric generators 113a, 113b, 113c, 113d, respectively. In the iterative decoder 114, the metric values obtained by the deinterleavers 21a, 21b, 21c, 21d are subjected to decoding corresponding to the encoding of the encoders 92a, 92b, 92c, 92d and the encoder 90.

According to the communication system having such a configuration, the metric values of the data assigned to the same multiplexed symbol whose reliability is successively deteriorated due to the fading or the like, can be dispersed. Therefore, influence from successive deterioration in the reliability can be dispersed and the degradation in the receiving characteristics can be restricted.

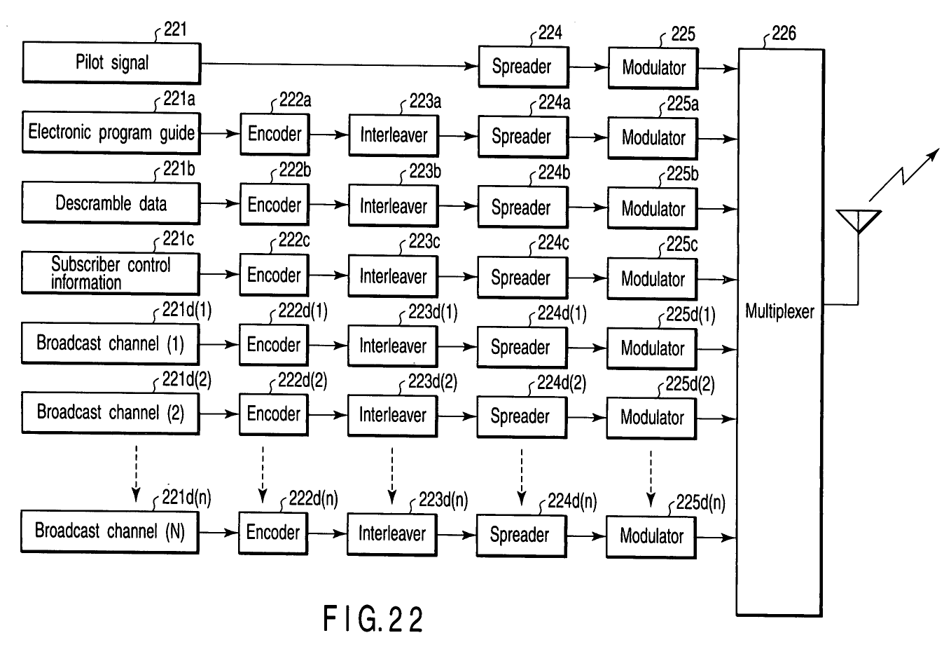

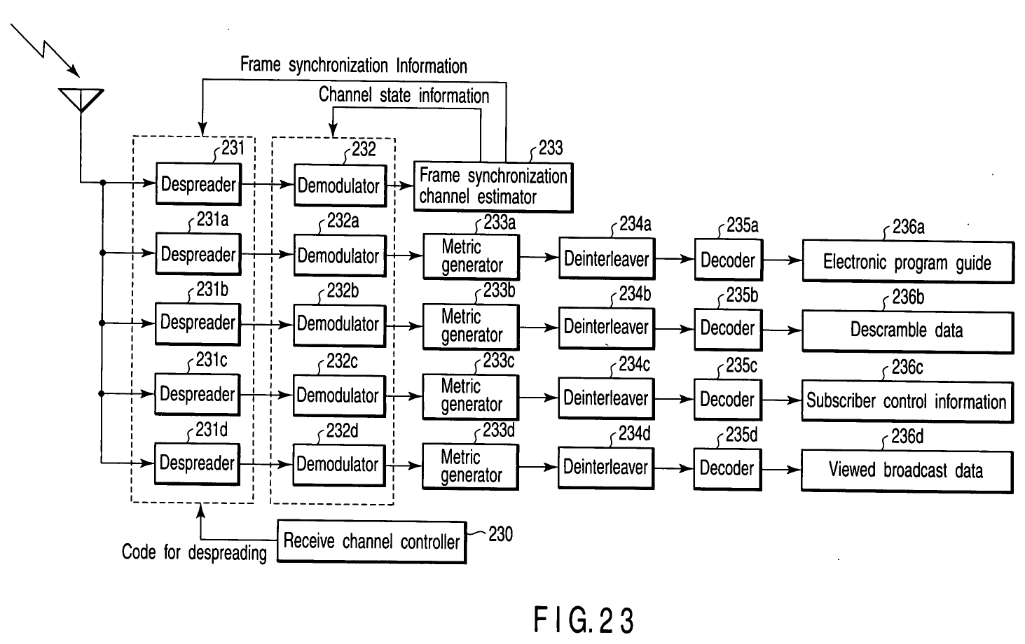

Next, application of the above-described scheme to the code division multiplexing broadcast system standardized by ITU-R Recommendation BO.1130-4, Digital System E, will be explained. FIG. 22 shows a configuration of a transmitting station and FIG. 23 shows a configuration of a receiving station.

In the configuration of FIG. 9, three information items 91a, 91b, 91c are input as the information from the information sources. In the code division multiplexing broadcast system, broadcast channel data 221d(1) to 221d(n) are multiplexed and transmitted in the CDM together with a pilot signal 221, electronic program guide 221a, descramble data 221b, and subscriber control information 221c, as shown in FIG. 22.

Information bit sequences of the electronic program guide 221a, descramble data 221b, subscriber control information 221c, and broadcast channel data 221d(1) to 221d(n) are encoded by encoders 222a, 222b, 222c, 222d(1) to 222d(n), respectively, to obtain encoded bit sequences.

Interleavers 223a, 223b, 223c, 223d(1) to 223d(n), interleave the encoded bit sequences obtained by the encoders 222a, 222b, 222c, 222d(1) to 222d(n), respectively. Spreaders 224, 224a, 224b, 224c, 224d(1) to 224d(n), spread carriers by using the pilot signal and the processing results of the interleavers 223a, 223b, 223c, 223d(1) to 223d(n), respectively.

Modulators 225, 225a, 225b, 225c, 225d(1) to 225d(n), execute modulation by using the spreading results of the spreaders 224, 224a, 224b, 224c, 224d(1) to 224d(n), respectively. The modulation results of the modulators are multiplexed by a multiplexer 226 and then transmitted.

All of the broadcast channel data 221d(1) to 221d(n) are transmitted at any time irrespective of the channel viewed by the receiving station.

On the other hand, in the receiving station shown in FIG. 23, each of despreaders 231, 231a, 231b, 231c, 231d despreads a receive signal at a timing based on the frame synchronization information, by using a despread code supplied from a receive channel controller 230. The despreader 231 receives the signal including the pilot signal 221. The despreader 231a receives the signal including the electronic program guide 221a. The despreader 231b receives the signal including the descramble data 221b. The despreader 231c receives the signal including the subscriber control information 221c. The despreader 231d receives the signal including the data of the channel selected by the user, of the broadcast channel data 221d(1) to 221d(n).

On the basis of channel state information supplied from the receive channel controller 230, demodulators 232, 232a, 232b, 232c, 232d demodulate the despreading results of despreaders 231, 231a, 231b, 231c, 231d, respectively. The pilot signal 221 is demodulated by the demodulator 232.

A frame synchronization channel estimator 233 detects the frame synchronization information and obtains channel state information from which a channel is to be estimated, on the basis of the demodulation result of the demodulator 232, i.e., the pilot signal, and supplies the frame synchronization information and the channel state information to the despreaders 231, 231a, 231b, 231c, 231d and the demodulators 232, 232a, 232b, 232c, 232d.

On the basis of the demodulation results of the demodulators 232a, 232b, 232c, 232d, metric generators 233a, 233b, 233c, 233d generate metric values, respectively.

Deinterleavers 234a, 234b, 234c, 234d deinterleave the metric values obtained by the metric generators 233a, 233b, 233c, 233d, respectively. Decoders 235a, 235b, 235c, 235d decode the processing results of the deinterleavers 234a, 234b, 234c, 234d, respectively.

The decoders 235a, 235b, 235c execute the decoding corresponding to the encoders 222a, 222b, 222c. The decoder 235d selectively executes the decoding corresponding to any one of the encoders 222d(1) to 222d(n). As a result of the decoding, broadcast channel data item 236d to be viewed is obtained together with the electronic program guide 236a, the descramble data 236b, and the subscriber control information 236c.

In the receiving station having the above-described configuration, the receive channel controller 230 outputs the spread code corresponding to the broadcast channel designated by the user to the despreader 231d, to separate the data of the broadcast channel selected by the viewer from the transmit signal to which all of the broadcast channel data are multiplexed. The despreader 231d thereby executes receiving by multiplying the spread code with the receive signal.

For this reason, the pilot signal 221 for estimation of the frame synchronization information and transmission path information to receive the CDM signal, the electronic program guide 221a, and the descramble data 221b and the subscriber control information 221c of the broadcast data are received at any time. In addition, the broadcast data of only one channel selected by the user are decoded. Therefore, five kinds of multiplexed data, of all of the data multiplexed on the transmitting side are received at any time by the receiving station.

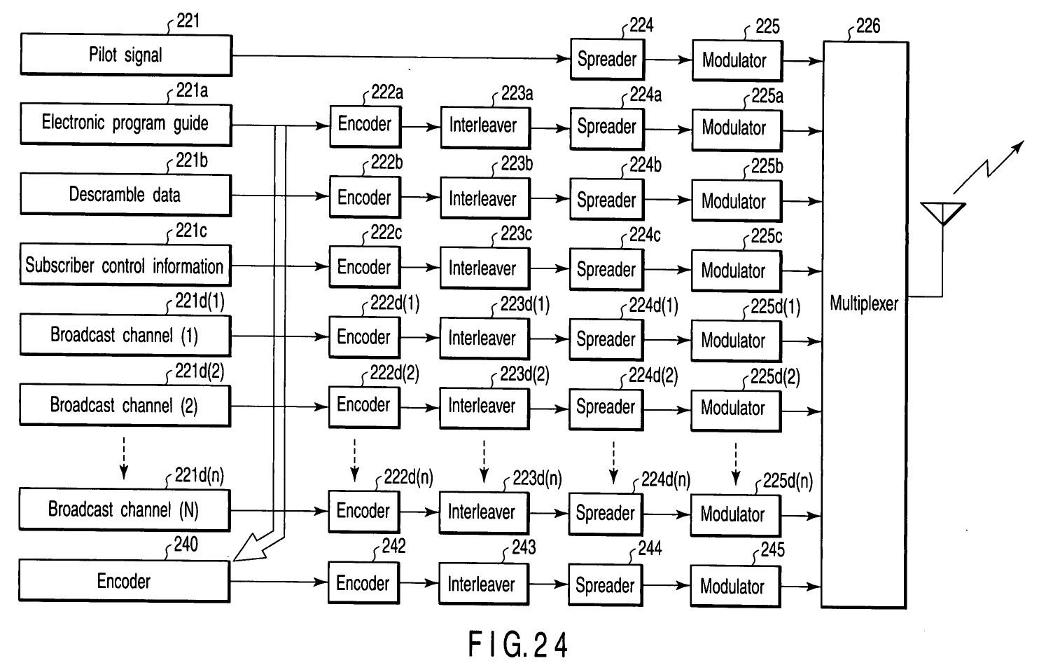

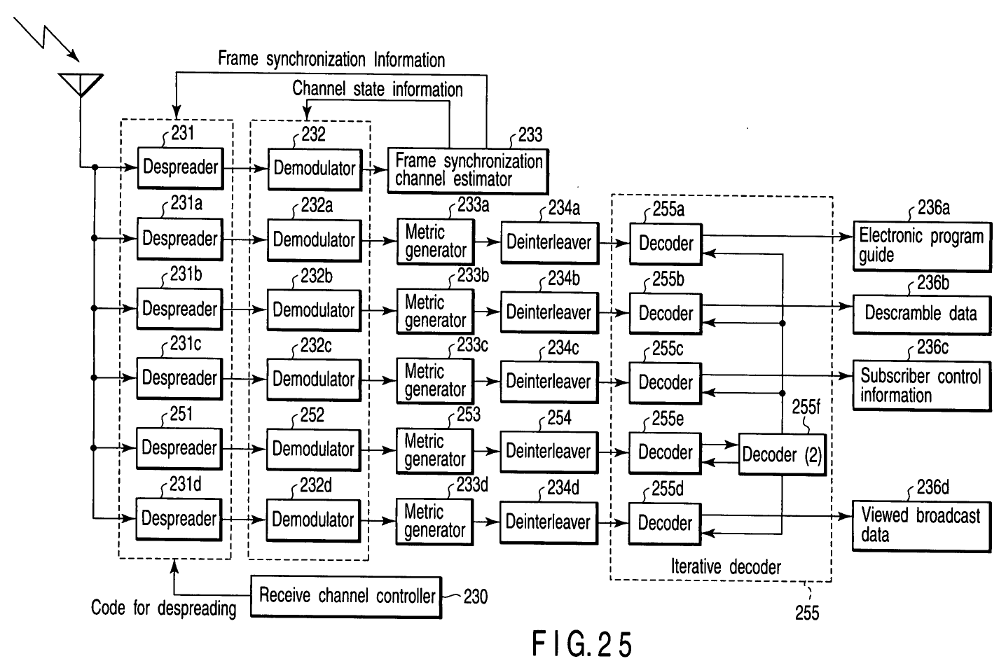

Next, application of the present invention to the above-described code division multiplexing broadcast system will be described. FIG. 24 shows a configuration of a transmitting station and FIG. 25 shows a configuration of a receiving station.

In the transmitting station shown in FIG. 24, an encoder 240, an encoder 242, an interleaver 243, a spreader 244 and a modulator 245 are added to the transmitting station shown in FIG. 22. Only differences between the transmitting station shown in FIG. 24 and the transmitting station shown in FIG. 22 will be explained below.

In accordance with the encoding of the encoders 222a, 222b, 222c, 222d(1) to 222d(n), the encoder 240 executes encoding by using the information bit sequences of the electronic program guide 221a, descramble data 221b, and subscriber control information 221c, and the broadcast channel data 221d(1) to 221d(n). IN the encoding executed by the encoder 240, a parity bit sequence is generated by using the information bit sequences, as shown in, for example, FIG. 10, FIG. 13 or FIG. 14.

In the encoder 242, the parity bit sequence is subjected to the same encoding as the encoders 222a, 222b, 222c, 222d(1) to 222d(n), and an encoded bit sequence is thereby obtained.

The interleaver 243 interleaves the encoded bit sequence obtained by the encoder 242. The spreader 244 spreads a carrier by using the processing result of the interleaver 243. The modulator 245 executes modulation by using the spreading result of the spreader 244. This modulation result is multiplexed with the modulation results of the modulators 225, 225a, 225b, 225c, 225d(1) to 225d(n) by the multiplexer 226 and then transmitted.

In the receiving station shown in FIG. 25, a despreader 251, a demodulator 252, a metric generator 253, and a deinterleaver 254 are added to the receiving station shown in FIG. 23. In addition, an iterative decoder 255 is provided instead of the decoders 235a, 235b, 235c, 235d.

Only differences between the receiving station shown in FIG. 25 and the receiving station shown in FIG. 23 will be explained below.

The despreader 251 despreads the receive signal at a timing based on the frame synchronization information, by using the despread code supplied from the receive channel controller 230. The despreader 251 thereby receives the signal including the parity bit sequence. The demodulator 252 demodulates the despreading result of the despreader 251, on the basis of the channel state information supplied from the receive channel controller 230.

The metric generator 253 generates a metric value on the basis of the demodulation result of the demodulator 252. The deinterleaver 254 deinterleaves the metric value obtained by the metric generator 253.

The iterative decoder 255 comprises decoders 255a, 255b, 255c, 255d, 255e, 255f. The decoders 255a, 255b, 255c, 25d, 255e, decode the processing results of the deinterleavers 234a, 234b, 234c, 234d, 254, respectively.

The decoders 255a, 255b, 255c execute the decoding corresponding to the encoders 222a, 222b, 222c. The decoder 255d selectively executes the decoding corresponding to any one of the encoders 222d(1) to 222d(n). The decoder 255e executes the decoding corresponding to the encoder 242.

In the decoder 255f, the decoding results of the decoders 255a, 255b, 255c, 255d, 255e are subjected to the decoding corresponding to the encoding of the encoder 240 and a parity bit sequence is thereby obtained. On the basis of the parity bit sequence corresponding to the encoder 240, the decoder 255f outputs the decoding results of the decoders 255a, 255b, 255c, 255d, 255e to the decoders 255a, 255b, 255c, 255d, 255e, respectively. On the basis of the corrected decoding results, the decoders 255a, 255b, 255c, 255d, 255e executes the decoding again.

After that, the decoding of the decoders 255a, 255b, 255c, 255d, 255e, 255f and the error correction of the decoder 255f are iterated. The error is lowered below a predetermined level soon and the electronic program guide 236a, the descramble data 236b, the subscriber control information 236c and the data 236d of the viewed broadcast channel are obtained.

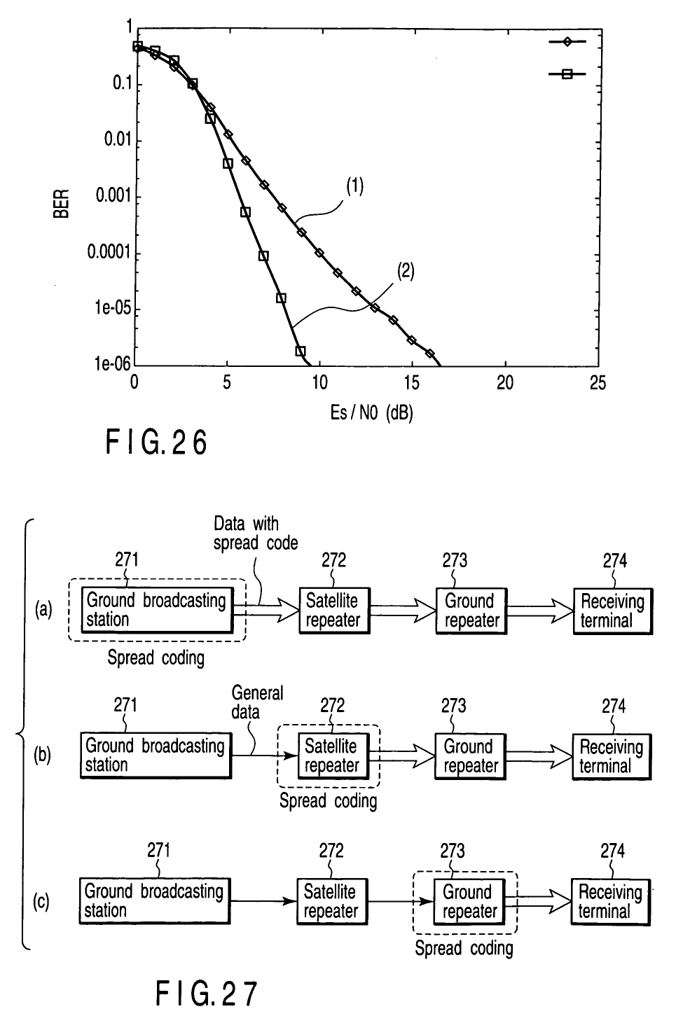

In the broadcast system having the above-described configuration, the parity bit sequence is generated on the basis of the information bit sequences of the electronic program guide 236a, the descramble data 236b, the subscriber control information 236c, and the broadcast channel data 221d(1) to 221d(n), and the parity bit sequence and the modulation results based on the information bit sequences are multiplexed and transmitted. In the receiving station, the parity bit sequence is decoded and the information bit sequences are decoded on the basis of the decoded parity bit sequence. Therefore, even if the orthogonality of the multiplexed information bit sequences cannot be maintained in the communication path, the degradation in the receiving characteristics can be restricted. It is assumed that the broadcast system (1) shown in FIG. 22 and FIG. 23 has thirty channels of the multiplexed data including the control information. It is also assumed that the broadcast system (2) shown in FIG. 24 and FIG. 25 has thirty channels of the multiplexed data including the control information and thirty-one channels including the parity bit sequence are multiplexed. FIG. 26 shows receive bit error rate characteristics of both the broadcast systems.

As the condition to obtain the characteristics, an urban multipath environment modeled by 3rd Generation Partnership Project (3GPP), i.e. International Mobile Telecommunication 2000 (IMT2000) is set as the communication path.

Since the broadcast system (2) has more multiplexed data channels by one than the broadcast system (1), the interference amount of the data caused by the multipath is greater. In the broadcast system (2), however, the decoding of the broadcast system (1) and decoding of the new parity bit sequence are iterated in the receiving station. Therefore, the receive bit error rate characteristic is improved as shown in FIG. 26.

Such an improvement of the characteristic indicates that since the correlation information of the multiplexed data in the communication path can be ideally used for the multiplexed data at the time of decoding in the decoder 255f corresponding to the encoder 240, the multiplexed receive signal can be optimally received.

In the broadcast system (2), the parity bit sequence generated by the newly added encoder 240 is multiplexed similarly to the other normal data. For this reason, the receiving operation can be executed even in the receiving station shown in FIG. 23, similarly to the case where the transmitting station has the configuration shown in FIG. 22.

In the broadcast system (2), the number of the receive channels in the receiving station shown in FIG. 25 is smaller than the number of the multiplexed channels in the transmitting station shown in FIG. 24 and all of the channels used by the encoder 240 is not used in the receiving station. In the receiving station, considering that the data of the channel which is not received by the receiving station is punctured, the decoder 255f may execute the decoding without using the channel data.

Incidentally, the code division multiplexing broadcast system standardized by the ITU-R is composed of the system which simultaneously executes distribution of the broadcast data using a broadcast satellite and distribution of the broadcast data using a ground repeater.

The transmitting station shown in FIG. 24 can be applied to a ground broadcasting station 271 as shown in FIG. 27(a), a satellite repeater 272 as shown in FIG. 27(b), or a ground repeater 273 as shown in FIG. 27(c). In any of the configurations, the advantage of improvement of the receiving characteristic can be obtained. A receiving terminal 274 in FIG. 27 corresponds to the receiving station in FIG. 25.

If the transmitting station is applied to the ground broadcasting station as shown in FIG. 27(a), an existing satellite repeater and an existing ground repeater can be used without modification.

The applied system of the present invention is not limited to the broadcast system. For example, it can also be applied to large-capacity relay communication using the multiplexing in repeater lines of subscriber telephones.

The present invention is not limited to the embodiments described above but the constituent elements of the invention can be modified in various manners without departing from the spirit and scope of the invention. Various aspects of the invention can also be extracted from any appropriate combination of a plurality of constituent elements disclosed in the embodiments. Some constituent elements may be deleted in all of the constituent elements disclosed in the embodiments. The constituent elements described in different embodiments may be combined arbitrarily.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A radio communication system with a transmitting station which multiplexes different data and transmits multiplexed data to a receiving station, comprising:
a transmitting station comprising:
a first encoding unit configured to generate plural parity information by using the different data;
a second encoding unit configured to encode each of the plural parity information and each of the different data to produce plural encoded data;
a modulation unit configured to modulate carriers by the plural encoded data to generate plural modulated signals; and
a multiplex unit configured to multiplex the plural modulated signals for outputting a multiplexed signal; and
a receiving station comprising:
a demultiplex unit configured to demultiplex the multiplexed signal transmitted from the transmitting station into the plural modulated signals;
a demodulation unit configured to demodulate each of the modulated signals demultiplexed by the demultiplex unit to produce plural demodulated signals;
a first decoding unit configured to decode each of the demodulated signals according to a decoding scheme corresponding to an encoding scheme of the second encoding unit to produce plural decoded signals; and
a second decoding unit configured to decode each of the decoded signals according to a decoding scheme corresponding to an encoding scheme of the first encoding unit to obtain the different data.

2. The radio communication system according to claim 1, wherein the first encoding unit extracts bits transmitted at a common timing, from bit sequences included in the different data, and generates the parity information.

3. The radio communication system according to claim 1, wherein the first encoding unit extracts bits transmitted at a constant different timing, from bit sequences included in the different data, and generates the parity information.

4. The radio communication system according to claim 1, wherein the first encoding unit extracts bits at random, from bit sequences included in the different data, and generates the parity information.

5. The radio communication system according to claim 1, wherein the transmitting station further comprises an interleaving unit configured to interleave each of the data encoded by the second encoding unit;
the modulation unit modulates the data interleaved by the interleaving unit;
the receiving station further comprises a deinterleaving unit configured to deinterleave the demodulated signals of the demodulation unit; and
the first decoding unit decodes an output of the deinterleaving unit according to a decoding scheme corresponding to an encoding scheme of the second encoding unit.

6. The radio communication system according to claim 1, wherein the first encoding unit is configured to generate first parity information, and the second encoding unit is configured to encode the different data and the first parity information to generate second parity information, and which further includes a third encoding unit configured to encode each of the first parity information, the second parity information and the plurality of different data to produce encoded data;
the modulation unit modulates each of the encoded data of the third encoding unit; and
the receiving station further comprises a first decoding unit configured to decode the encoded data of the third encoding unit according to a decoding scheme corresponding to an encoding scheme of the third encoding unit to produce decoded data, a second decoding unit configured to decode the encoded data of the third encoded unit according to a decoding scheme corresponding to an encoding scheme of the second encoding unit by which encoding the second parity information is encoded, and a third decoding unit configured to decode the decoded data of the second decoding unit according to a decoding scheme corresponding to an encoding scheme of the first encoding unit to obtain the different data.

7. The radio communication system according to claim 1, wherein the transmitting station is a broadcasting ground station.

8. The radio communication system according to claim 1, wherein the transmitting station comprises a repeater which repeats a signal transmitted from a broadcasting ground station to another repeater or a receiving terminal to receive broadcasting.

9. A transmitter used in a radio communication system for transmitting a multiplexed signal including different data to a receiver comprising:
a first encoding unit configured to generate parity information by using the different data;
a second encoding unit configured to encode each of the parity information and each of the different data to produce plural encoded data;
a modulation unit configured to modulate carriers by the plural encoded data to generate plural modulated signals; and
a multiplex unit configured to multiplex the plural modulated signals for outputting the multiplexed signal.

10. A decoding apparatus in a radio communication system which receives a signal transmitted from a transmitting station comprising a first encoding unit configured to generate parity information, a second encoding unit configured to encode each of the parity information and each of the different data to produce plural encoded data, a modulation unit configured to modulate each of the encoded data of the second encoding unit for producing plural modulated signals, and a multiplex unit configured to multiplex the modulated signals for output a multiplexed signal,
the decoding apparatus comprising:
a demultiplex unit configured to demultiplex the multiplexed signal transmitted from the transmitting station into the plural modulated signals;
a demodulation unit configured to demodulate each of the modulated signals demultiplexed by the demultiplex unit to produce plural demodulated signals;
a first decoding unit configured to decode each of the demodulated signals according to a decoding scheme corresponding to an encoding scheme of the second encoding unit to produce plural decoded signals; and
a second decoding unit configured to decode each of the decoded signals according to a decoding scheme corresponding to an encoding scheme of the first encoding unit to obtain the different data.
